(19) United States
(12) Patent Application Publication
(10) Pub. No.: US 2009/0145649 A1
(43) Pub. Date: Jun. 11, 2009

(54) MULTI-LAYERED WIRING SUBSTRATE, METHOD FOR PRODUCING THE SAME, AND SEMICONDUCTOR DEVICE

(75) Inventors: Michio HORIUCHI, Nagano-shi (JP); Yasue Tokutake, Nagano-shi (JP); Shigeaki Suganuma, Nagano-shi (JP); Naoyuki Koizumi, Nagano-shi (JP); Fumimasa Katagiri, Nagano-shi (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD., Nagano-shi (JP)

(21) Appl. No.: 12/323,950

(22) Filed: Nov. 26, 2008

(30) Foreign Application Priority Data
Nov. 29, 2007 (JP) 2007-309147

(51) Int. Cl. H05K 1/18; H05K 1/11; H05K 3/10

(52) U.S. Cl. 174/260; 174/261; 29/846

(57) ABSTRACT

A multi-layered wiring substrate, in which a wiring layer and an insulative layer are alternately arranged, having pads to connect to electronic components at one side thereof and wires to connect the corresponding pads to the wiring layer, is composed so that the multi-layered wiring substrate is provided with through holes in which a resin material is filled, at least a part of the pads is formed on the resin material, and at least a part of the wire is contained in the resin material.

### BACKGROUND OF THE INVENTION

The present invention relates to a multi-layered wiring substrate, and in further detail, to a multi-layered wiring substrate that is capable of remarkably relieving a problem in regard to channels for rerouting of many high density I/Os, capable of reducing the conductor loss by relieving micronization of wirings and shortening the wiring length, capable of reducing the crosstalk, capable of shortening and simplifying the design process, capable of lowering the production costs, and capable of achieving improvement in reliability and yield. In particular, the present invention relates to a multi-layered wiring substrate for flip-chip packaging various types of semiconductor elements, and a method for producing the same, and also to a semiconductor device using such a multi-layered wiring substrate.

Recently, in line with micronization and high performance of a semiconductor device, the number of electrode terminals of a semiconductor element (hereinafter, it may be referred to as “semiconductor chip”) mounted on a semiconductor device has been increased. To cope therewith, conventionally, such a method is adopted by which a semiconductor chip is mounted on a wiring substrate by flip-chip packaging after electrode terminals are formed in the form of an area array on a surface where electrode terminals of the semiconductor chip are formed. According to the flip-chip packaging, electrode terminals can be electrically connected to external connection terminals by connecting a bump formed on the electrode terminal of a semiconductor element to an external connection terminal (bump) of a wiring substrate. In addition, in order to cope with micronization of a wiring pattern, a method of using a plurality of layers of wiring substrates arranged, a so called “built-up method” is adopted.

Where flip-chip packaging is carried out in a multi-layered wiring substrate, such a basic structure is adopted, in which at the side of a wiring substrate that receives a bump matrix of flip chips, a wiring pattern is guided so that internally existing pads of the pad lines on the wiring substrate pass through the clearance between adjacent pads on the first layer of the uppermost layer, and the pad is taken out to the outside. When the pads cannot be taken out to the outside the bump matrix on the first layer, the pads are rerouted to the via receiving pads, and may be drawn out through the via on the second or subsequent layers. A multi-layered wiring substrate having such a rerouting structure has been publicly known. For example, a semiconductor device 90 as shown in FIG. 12 attached to the present specification is disclosed in Patent Document 1. The semiconductor device 90 illustrated herein uses a ceramic multi-layered wiring substrate 93 as a wiring substrate, and a semiconductor element 92 is packaged upward thereof by a flip-chip connection. The multi-layered wiring substrate 93 has a bump connection pad 96 on the surface on which the semiconductor element 92 is packaged, and has an external connection pad 97 on the surface opposite to the element-packaged surface. A bump 95 is disposed on the underside of the semiconductor element 92. By connecting the bump 95 to the bump connecting pad 96, the semiconductor element 92 can be packaged on the multi-layered wiring substrate 93. In addition, a conductor wiring 98 is formed, as in the illustrated pattern, in the interior of the multi-layered wiring substrate 93, wherein the bump connecting pad 96 is connected to one end part of the conductor wiring 98, and an external connection pad 97 is connected to the other end part thereof. A solder ball 94 which functions as the external connection terminal is connected to the external connection pad 97. Further, an underfilling material 99 is caused to intervene between the semiconductor element 92 and the multi-layered wiring substrate 93. However, in such a semiconductor device, there is a problem that the weight thereof is increased in line with an increase in the number of arrangements of the multi-layered wiring substrate.

Also, a semiconductor device that has solved the above-described problem is disclosed in Patent Document 1. That is, Patent Document 1 describes a wiring substrate that includes a sheet-like formed insulative resin, electrodes formed at predetermined positions on the insulative resin, a coated wire that is composed by coating the surface of the conductor wire with an insulative material, electrically connects between the electrodes, and has a part thereof exposed from the insulative resin, and a conductor resin formed on the insulative resin so that it seals the coated wire exposed onto the insulative material. Describing in detail, as shown in FIG. 13 attached to the present specification, a semiconductor device 100 includes a wiring substrate 110, a semiconductor element 112 packaged thereon, and solder balls 114. The wiring substrate 110 is composed of bump connection pads 116, external connection pads 117, a conductor resin 122 and an insulative resin 120. In addition, the semiconductor element 112 has a plurality of bumps 115. The semiconductor element 112 is connected to the bump connection pad 116 of the wiring substrate 110 by means of a flip-chip technology, and an underfilling material 119 is buried between the semiconductor element 112 and the wiring substrate 110 in order to absorb stresses occurring during connection. Further, the coated wires 118 are wire bonded between the bump connection pads 116 and the external connection pads 117. The solder balls 114 are to package a board 130.

However, as has been recognized in the above-described example, in a prior art multi-layered wiring substrate, since the connection surface of a semiconductor element is the same as that where external connection terminals are formed, it is necessary that the height of the external connection terminal is designed to be greater than at least the height of the semiconductor element. For example, where solder balls are used as the external connection terminal, it is not possible to achieve high density connections because the ball diameter is increased, wherein there is a problem by which the area of the semiconductor device is increased. In addition, in relation thereto, there is another problem in that the height of the entire semiconductor device is reduced.

Further, in a multi-layered wiring substrate for flip-chip packaging, it is requisite that the drawing wires are micronized in line with a decrease in the bump pitch. In detail, there has been a tendency that, in line with high performance of a system, the number of flip chip I/Os has increased, the pitch of bumps, that is, gaps between the receiving pads (through which the wirings are drawn out) have been gradually narrowed. In line therewith, a production process to form wirings has become difficult, wherein a lowering in the yield is brought about. According to the information and knowledge of the present inventors, there is a tendency that the relationship between the pump pitch and the diameter of receiving pads will change as follows.

(1) 350 μm/200 μm→(2) 240 μm/110 μm→(3) 200 μm/90 μm

Also, under such a relationship between the bump pitch and the receiving pad diameter, the wiring width/wiring interval, which is necessary to draw out two or three pad lines, becomes as follows, in each of the above-described relationship (1), (2) or (3).

(1) 50 μm/50 μm (case of two lines), 30 μm/30 μm (case of three lines)
(2) 43 μm/43 μm (case of two lines), 26 μm/26 μm (case of three lines)
(3) 36 μm/36 μm (case of two lines), 22 μm/22 μm (case of three lines)

In consideration of the above-described tendency, it can be expected that the bump pitch will be narrowed to 100 μm or less. On the other hand, it is not possible that the bump pitch and the receiving pad diameter are made remarkably small in regard to reliability of bump connection. Therefore, narrowing of the pitch becomes further remarkable. For example, when the receiving pad diameter is 70 μm, wiring widths of 10 μm/10 μm or 6 μm/6 μm are required in order to achieve one or two wirings in regard to the bump pitch of 100 μm. However, with the wiring forming technology on a prior art organic substrate, the yield is remarkably lowered where the wiring width is 10 μm or less, and it is considered that formation of wiring itself becomes impossible for the wiring width of 6 μm or less. Although it is considered that an inorganic substrate such as ceramic or silicon is used instead of an organic substrate in order to achieve such minute wirings, and wirings are formed on the inorganic substrate by a sputtering technology, it is impossible to avoid an increase in the production costs in addition to an increase in weight. Also, even if minute wirings can be formed, the characteristics of minute wirings thus obtained will pose a problem. For example, there are several problems, that is, an increase in the wiring resistance in line with micronization, a parasitic capacity in line with high dielectric constant where the substrate is ceramic.

### [Patent Document 1] Japanese Published Unexamined Patent Application No. 2000-323516 (Claims, FIGS. 1 and 5)

### SUMMARY OF THE INVENTION

It is therefore an object of the present invention to provide a multi-layered wiring substrate for flip-chip packaging, which can solve the above-described problems in prior art multi-layered wiring substrates for flip-chip packaging and can respond to high density and high performance of a system, and a method for producing the same. In detail, a multi-layered wiring substrate that is an object of the present invention is capable of remarkably relieving a problem in regard to channels for rerouting of many high density I/Os, capable of reducing the conductor loss by relieving micronization of wirings and shortening the wiring length, capable of reducing crosstalk, capable of shortening and simplifying the design process, capable of lowering production costs, and capable of achieving improvement in reliability and yield.

It is another object of the present invention to provide a semiconductor device which adopts such a multi-layered wiring substrate and can respond to high density and high performance of a system. In addition, it is still another object of the present invention to make it unnecessary to form large external connection terminals in order to reduce the height of the entire semiconductor device.

These and other objects of the present invention can be easily understood based on the detailed description given below.

According to a first aspect of the invention, there is provided a multi-layered wiring substrate including:

a wiring layer and an insulation layer alternately arranged, and

at one side thereof, pads connected to electronic components and wires for connecting the pads to the wiring layers, wherein

through holes filled with a resin material are provided in the multi-layered wiring substrate,

at least apart of the pad is formed on the resin material, and

at least a part of the wire is contained in the resin material.

According to a second aspect of the invention, there is provided the multi-layered wiring substrate according to the first aspect, wherein

the through holes are provided so that at least the area at which the pad is provided is contained in the through holes.

According to a third aspect of the invention, there is provided the multi-layered wiring substrate according to the first or second aspect, wherein

the wire is made of a wire material of conductor metal, of a wire material of conductor metal and an insulative coating layer to coat the outer circumference of the wire material of conductor metal, or of a wire material of conductor metal, an insulative coating layer to coat the outer circumference of the wire material of conductor metal one by one and a conductor layer.

According to a forth aspect of the invention, there is provided the multi-layered wiring substrate according to the first or second aspect, wherein

the wire is made of a wire material of conductor metal, an insulative coating layer to coat the outer circumference one by one and a conductor layer to be a co-axial structure, and

in the co-axial structure wire, a ratio of the inner diameter D0 of the conductor layer to the outer diameter D1 of the wire is within the range of 1:3 to 6.

According to a fifth aspect of the invention, there is provided the multi-layered wiring substrate according to any one of the first to forth aspects, wherein

an organic resin material is filled in the through holes.

According to a sixth aspect of the invention, there is provided the multi-layered wiring substrate according to the fifth aspect, wherein

the organic resin material is a metallic particle-dispersed type organic resin material.

According to a seventh aspect of the invention, there is provided the multi-layered wiring substrate according to the fifth aspect, wherein

the organic resin material is an organic resin material having a low resiliency ratio.

According to an eighth aspect of the invention, there is provided the multi-layered wiring substrate according to any one of the first to seventh aspects, wherein

in the multi-layered wiring substrate, the wiring layers are electrically connected to each other by a vertical wiring portion.

According to a ninth aspect of the invention, there is provided a method for producing a multi-layered wiring substrate according to the first aspect, including the steps of:

preparing a multi-layered wiring substrate in which a through hole is provided at a position corresponding to a portion, at which a pad to be electrically connected to an electronic component is formed, and a wiring layer and an insulative layer are alternately arranged;

preparing a metallic foil provided, at predetermined portions, with positions where a pad to be electrically connected to an electronic component is formed and a wiring pattern to be electrically connected to the multi-layered wiring substrate is formed, respectively;

connecting the multi-layered wiring substrate with the metallic foil;

electrically connecting the portion, at which the pad of the metallic foil is formed, with the wiring layer of the multi-layered wiring substrate by means of wires;

filling a resin material in the through holes; and

forming the pads and the wiring pattern at the predetermined portions by patterning the metallic foil.

According to a tenth aspect of the invention, there is provided a method for producing a multi-layered wiring substrate according to the first aspect, including the steps of:

preparing a metallic foil provided, at predetermined positions, with portions where a pad to be electrically connected with an electronic component and a wiring pattern serving as a wiring layer of an outermost layer at a multi-layered wiring substrate to be obtained are respectively formed;

arranging an insulative layer provided with an opening at which the pad is formed, on the metallic foil;

forming a wiring layer on the insulative layer;

electrically connecting a portion of the metallic foil, at which the pad is formed, with the wiring layer by means of wires;

filling the opening with a resin material; and

forming the pad and the wiring pattern at the predetermined portions by patterning the metallic foil.

According to an eleventh aspect of the invention, there is provided the method for producing a multi-layered wiring substrate according to the tenth aspect, wherein

the step of arranging an insulative layer on the metallic foil and the step of forming a wiring layer on the insulative layer are repeated over a plurality of times.

According to a twelfth aspect of the invention, there is provided the method for producing a multi-layered wiring substrate according to any one of the ninth to eleventh aspects, wherein

after the step of connecting by means of wires and before the step of patterning the metallic foil,

an opening is formed at a portion, corresponding to the vertical wiring portion to connect the wiring layers of the multi-layered wiring substrates to each other, of the metallic foil,

the insulative layer of the multi-layered wiring substrate exposed at the opening is selectively etched using the metallic foil as a mask to form a through hole which reaches the wiring layer of the multi-layered wiring substrate, and

the vertical wiring portion to connect the metallic foil and the wiring layer of the multi-layered wiring substrate to each other is formed by filling the through hole with conductor metal.

According to a thirteenth aspect of the invention, there is provided a semiconductor device including:

a multi-layered wiring substrate according to the first aspect,

a pad for connecting an electronic component provided at one side of the multi-layered wiring substrate,

an electronic component connected to the pad, and an external connection terminal provided at the other side of the multi-layered wiring substrate.

According to the present invention, a number of advantages can be obtained as can be understood based on the detailed description given below. For example, in the present invention, an opening specifically called a “through hole” in the present invention is provided particularly at a signal portion of the multi-layered wiring substrate, a pad drawing-out wiring is carried out with a conductor wire in the through hole, and furthermore, the conductor wire is bent and is three-dimensionally disposed, wherein it is possible to remarkably relieve the problem in regard to channels for rerouting of several thousands or more high density I/Os, which has been a problem in the multi-layered wiring substrate, and it is also possible to reduce the conductor loss by relieving the micronization of wirings and shortening the wiring length. Further, since the conductor wire is composed so as to have a coaxial structure instead of being composed of single-wired conductor metal, the crosstalk can be reduced, wherein by entirely coating the conductor wire having a coaxial structure with a conductor, a lowering in EMI (electromagnetic interference) can be brought about. Still further, the heat radiation characteristics can be improved by filling a specified organic resin material in the through holes of the multi-layered wiring substrate. In addition to these advantages, with the present invention, the design process can be shortened and simplified, wherein it is possible to reduce the production costs and to improve the reliability and the yield in production.

Also, since connection terminals and external connection terminals of a semiconductor element are in an exposed state and although no semiconductor element is built in the multi-layered wiring substrate, it is possible to meet diversified requests from manufacturers of semiconductor devices. In particular, according to the present invention, it is possible to make the surface on which the semiconductor elements are connected different from the surface where the external connection terminals are formed, high density packaging is enabled, and semiconductor elements can be packaged without increasing the area of the semiconductor device even in cases of semiconductor elements having a number of I/Os.

### BRIEF DESCRIPTION OF THE DRAWINGS

FIG. 1 is a sectional view showing a preferred embodiment of a multi-layered wiring substrate according to the present invention;

FIG. 2 is a sectional view showing another preferred embodiment of the multi-layered wiring substrate according to the present invention;

FIG. 3 is a sectional view showing still another preferred embodiment of the multi-layered wiring substrate according to the present invention;

FIG. 4 is a sectional view showing still further another preferred embodiment of the multi-layered wiring substrate according to the present invention;

FIGS. 5(A) to 5D) are sectional views showing one method for producing a conductor wire having a coaxial structure that can be used in a multi-layered wiring substrate according to the present invention;

FIG. 6 is a sectional view showing a preferred embodiment of a semiconductor device according to the present invention;

FIG. 7 is a sectional view showing another preferred embodiment of the semiconductor device according to the present invention;

FIG. 8 is a sectional view showing still another preferred embodiment of the semiconductor device according to the present invention;

FIGS. 9(A) to 9(G) are sectional views sequentially showing a method (part 1) for producing a multi-layered wiring substrate shown in FIG. 4;

FIGS. 10(A) to 10(D) are sectional views sequentially showing a method for forming a vertical wiring portion in production of a multi-layered wiring substrate shown in FIG. 4;

FIGS. 11(A) to 11(I) are sectional views sequentially showing another method for producing a multi-layered wiring substrate shown in FIG. 4;

FIG. 12 is a sectional view showing one example of a prior art multi-layered wiring substrate; and

FIG. 13 is a sectional view showing another example of the prior art multi-layered wiring substrate.

### DETAILED DESCRIPTION OF THE PREFERRED EMBODIMENTS

According to the present invention, a multi-layered wiring substrate, a method for producing the same and a semiconductor device can be advantageously carried out in various modes, respectively. Hereinafter, although a description is given of a preferred embodiment of the present invention with reference to the attached drawings, the present invention is not limited by the following embodiments.

One of the aspects of the present invention exists in a multi-layered wiring substrate. A multi-layered wiring substrate according to the present invention is preferably a multi-layered wiring substrate composed so that two or more wiring layers and insulative layers are arranged one by one, for example, a multi-layered wiring substrate for flip-chip packaging. The multi-layered wiring substrate for flip-chip packaging is featured in, for example,

(1) a group of pads (flip-chip receiving pads) or precursors thereof are provided on one side of the multi-layered wiring substrate,
(2) through holes being spacing having a predetermined shape are formed in areas adjacent to the flip-chip receiving pads in the interior of the multi-layered wiring substrate in order to expose the flip-chip receiving pads, and
(3) wirings, which are drawn out from the flip-chip receiving pads are composed of conductor wires, three-dimensionally bent in the through holes and are electrically connected to the wiring layers of the multi-layered wiring substrate on the same surface and/or a different surface.

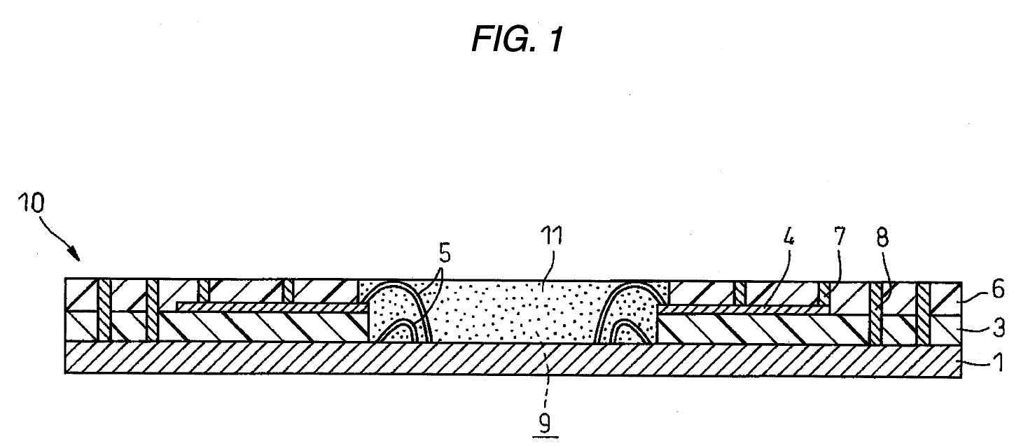

A multi-layered wiring substrate according to the present invention may have a configuration shown in FIG. 1. The illustrated multi-layered wiring substrate 10 exemplarily shows a multi-layered wiring substrate having a two-layered arranging structure, that is, a arranging structure in which two wiring layers and two insulative layers are arranged one by one, in order to easily achieve a layered configuration.

The multi-layered wiring substrate may basically have a configuration similar to a multi-layered wiring substrate, which has conventionally been used, as long as it has through holes to expose flip-chip receiving pads almost at the middle part thereof or places other than the middle part and a resin material is filled in the through holes. Also, the present invention aims particularly at improvement in flip-chip packaging as described above and explained below in detail. However, in embodiments of the present invention, the flip-chip receiving pads will have a mode of external connection terminals usually disposed in the form of area array, but may be external connection terminals of another mode, for example, one or more external connection terminals if necessary. Also, in the multi-layered wiring substrate 10 illustrated, although the number of arrangements of wiring layers and insulative layers is two, the number of arrangements is not limited thereto. As necessary, the number of arrangements may be three or more.

The wiring layer may be formed in an optional wiring pattern by an optional normal method. For example, the wiring layer may be advantageously formed by selectively etching a metallic foil. The metallic foil used for formation of the wiring layer is not particularly limited. However, for example, a conductor metallic foil such as nickel foil, cobalt foil, and copper foil may be listed, and preferably, a copper foil. The etching may be easily carried out by using a normal etchant such as, ferric chloride. Although the thickness of the wiring layer may be varied in a wide range, normally, it is in a range from approximately 8 μm to 18 μm.

Normally, although the wiring layer may be advantageously formed by selectively etching a metallic foil, it may be formed by a different method. For example, the wiring layer may be formed, for example, by electrolytic plating of conductor metal. As one example, areas other than an area, at which the wiring layer is intended to be formed, is masked by a resist, and the wiring layer may be formed by electrolytically plating conductor metal, such as gold, palladium, cobalt, nickel, etc., at a predetermined thickness.

The wiring layer may be formed in a predetermined wiring pattern and thickness adjacent to the insulative layer in the interior of the multi-layered wiring substrate or on the surface thereof. However, where the wiring layer is used on the uppermost layer or the lowermost layer of the multi-layered wiring substrate, it is preferable that external connection terminals (generally called “connection pads”) are formed at predetermined portions of the wiring layer in order to assist in the connection of various types of electronic components to the wiring layer and to connect the wiring layers to each other. In addition, a description is given of a general size of such external connection terminals. For example, in the case of circular terminals, the diameter thereof is approximately 100 μm to 200 μm, and the thickness thereof is approximately 5 μm to 30 μm. Also, these external connection terminals may have solder bumps, lands and other means on the surfaces thereof in order to increase the reliability of connection as necessary, as has been generally carried out in the field of wiring substrates.

The external connection terminal (connection pad) may be formed of a single layer or may be formed in the form of a complex pad having a multi-layered structure of two or more layers. The complex pad may be brought about by, for example, forming the first pad by plating a metal having a low melting point and continuously forming the second pad by plating a metal having a higher melting point than the low melting point. The metal having a low melting point may be preferably used in the form of an alloy. A suitable alloy having a low melting point may be, for example, a tin-lead (SnPb) alloy, a tin-silver (SnAg) alloy, a tin-copper-silver (SnCuAg) alloy, etc. Further, as described above, where the complex pad terminal is formed, it is preferable that formation of the first pad is carried out under the condition that the area of the pad thereby obtained is made larger than the area of the second pad.

The insulative layer may be formed with an optional thickness by an optional normal method as in the wiring layer. The insulative layer may be formed of an inorganic material such as ceramic as necessary. However, it is preferable that the insulative layer is formed of an insulative organic resin material. For example, the insulative layer may be formed by coating or potting a selected organic resin material at a predetermined thickness. For example, epoxy resin, polyimide resin, etc., may be listed as a suitable organic resin material. The thickness of the insulative layer may be varied in a wide range. However, the thickness thereof is normally in a range from approximately 20 μm to 500 μm.

Referring again to FIG. 1, a multi-layered wiring substrate 10 according to the present invention has insulative layers 3 and 6 vertically adjacent to each other. A wiring layer 4 is formed on the insulative layer 3 in a predetermined wiring pattern. Also, although not illustrated, a wiring layer may be formed on the insulative layer 6 as necessary. A penetration conductor (in the present invention, this portion is specifically called a “vertical wiring portion 7”), which is made of a penetration conductor metal, is formed in the insulative layer 6 so as to penetrate the same, and a vertical wiring portion 7 made of a penetration conductor metal is formed in the insulative layers 3 and 6 so as to penetrate the two layers. The vertical wiring portions may be formed by, for example, filling obtained through holes with a conductor metal by plating after opening the insulative layer by means of laser drilling. According to another method, the vertical wiring portions may be formed by inserting a column (post) of conductor metal in the through hole. Although, in the multi-layered wiring substrate 10 illustrated, nothing is formed on the upper part end surfaces of the vertical wiring portions 7 and 8, external connection terminals (connection pads) are normally formed in order to connect the multi-layered wiring substrate 10 to a motherboard. For example, the multi-layered wiring substrate 10 may be mounted on a motherboard via an external connection terminals and solder balls.

Here, a further detailed description is given of the vertical wiring portions 7 and 8 formed so as to penetrate the insulative layers 3 and 6. The vertical wiring portions are preferably formed of a conductor metal. The vertical wiring portions may be formed in various modes in the embodiment of the present invention. For example, the vertical wiring portions that connect wiring layers to each other may be formed by filling the through holes by plating a conductor metal after the through holes that penetrate the insulative layers are formed. According to another method, the vertical wiring portions may be formed by disposing columns (posts) of conductor metal, which have corresponding shapes and dimensions, at an optional stage of forming the multi-layered wiring substrate instead of plating a conductor metal.

Describing in still further detail, for example, where the vertical wiring portion is formed by plating a conductor metal, generally, it is formed by plating a conductor metal in the through hole that penetrates the insulative layer. In detail, for example, a resist is removed from the portion, at which the vertical wiring portion is to be formed, after the resist is coated on the entire surface of the insulative layer. Next, a conductor metal to form the vertical wiring portion, for example, copper (Cu), etc., is electrolytically plated at a predetermined thickness so as to cover the resist and the insulating layer which is the base of the resist. By removing the resist used as a mask, a conductor portion that is the object can be obtained. In addition, in the present invention, it is possible to form a desired vertical wiring portion by using an after-patterned metallic foil as a mask instead of the resist mask.

Where the vertical wiring portion is formed of a metallic column, generally, after a conductor wire is disposed on a metallic foil to form the wiring layer, the vertical wiring portion may be formed by providing a column (a so-called metallic column) made of a conductor metal like a post at a predetermined position of the metallic foil. The metallic column referred to herein may be a circular column or a square column. In some cases, it may be a thick conductor wire. With this method, the metallic column may be formed according to various techniques. The metallic column may be formed, for example, by burying a metallic column, or otherwise by filling a suitable conductor metal to form the metallic column or plating the same. In further detail, such formation of the metallic column may be carried out by using methods described in Japanese Published Unexamined Patent Application Nos. Hei-8-78581, Hei-9-331133, Hei-9-331134, Hei-10-41435, etc.

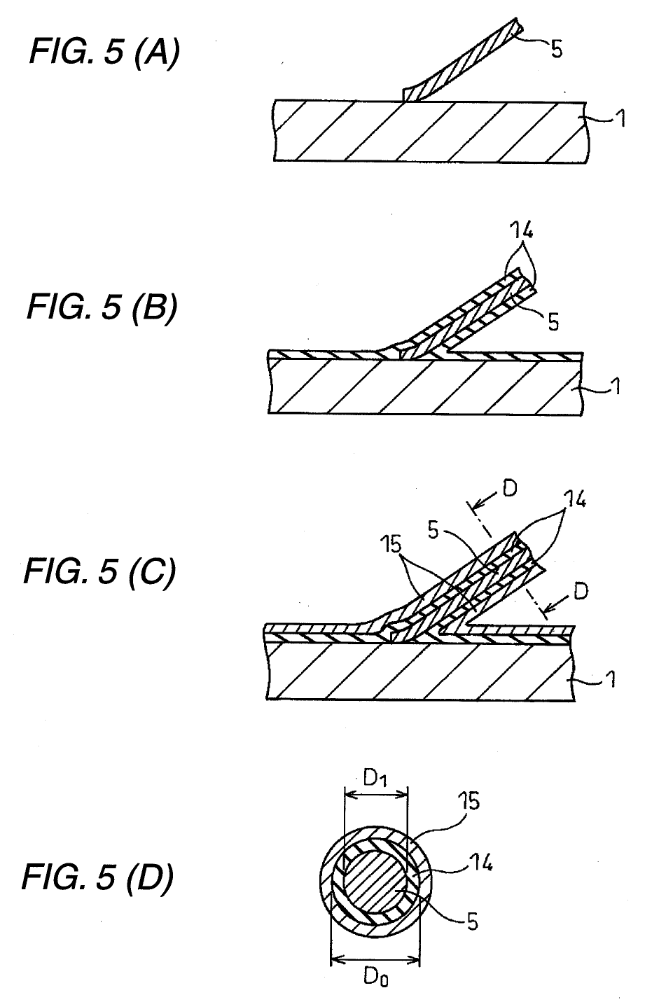

In the multi-layered wiring substrate 10 illustrated in FIG. 1, the metallic foil 1 indicates a precursor of a flip-chip receiving pad. That is, in the present invention, the metallic foil is thinned by selectively etching in the subsequent etching process, wherein the flip-chip receiving pad and wiring layer may be formed. As described in FIGS. 5(A) to 5(D), etc., using reference numeral 22, the flip-chip receiving pads are in the form of an area array set of a group of external connection terminals (connection pads) prepared to make flip-chip connections, and may be formed and structured as in the above-described external connection terminals.

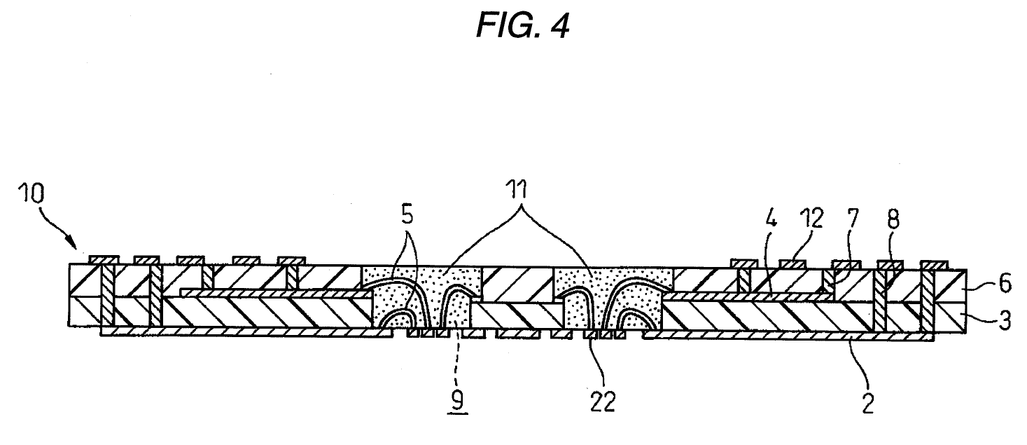

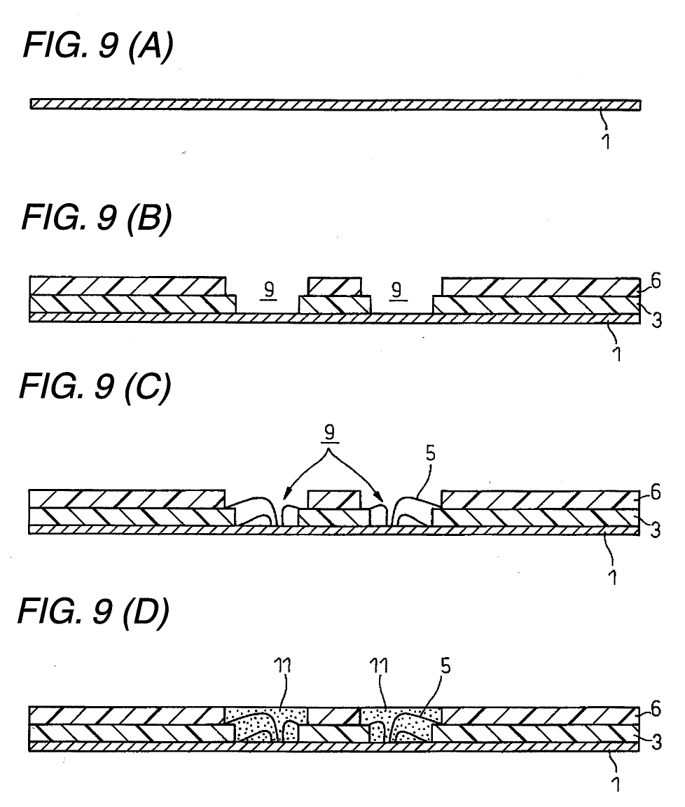

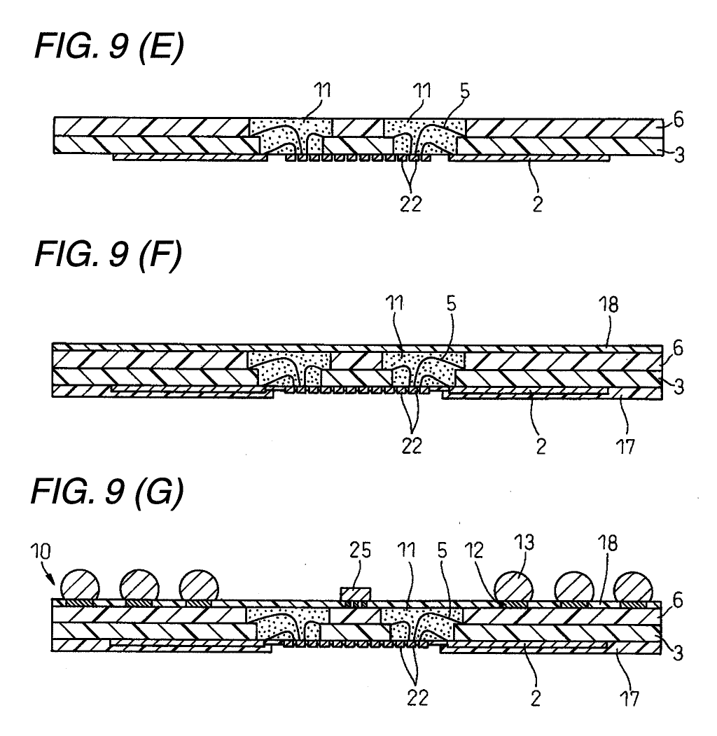

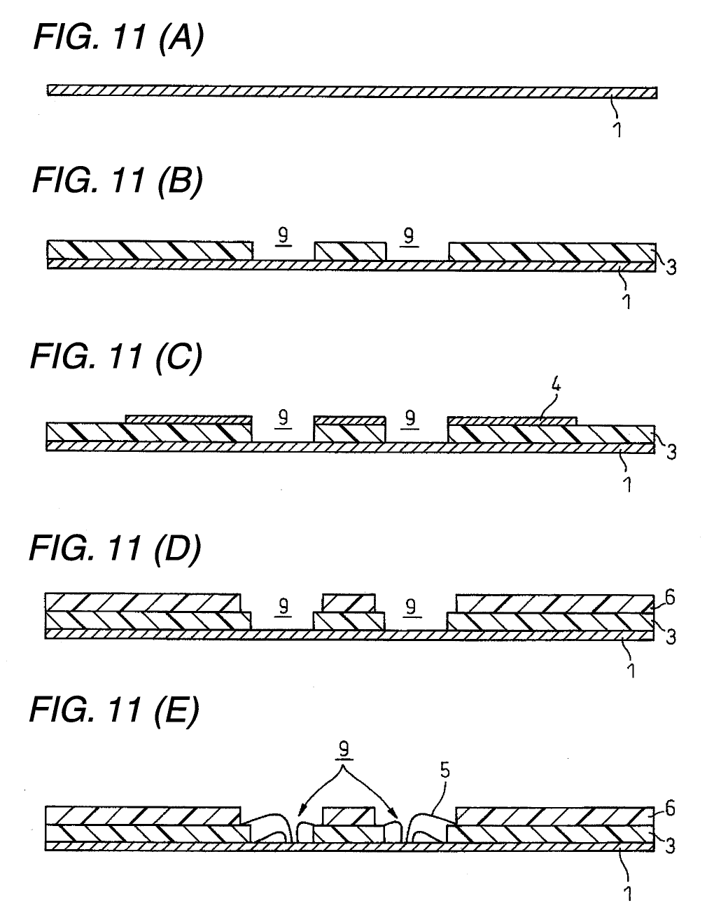

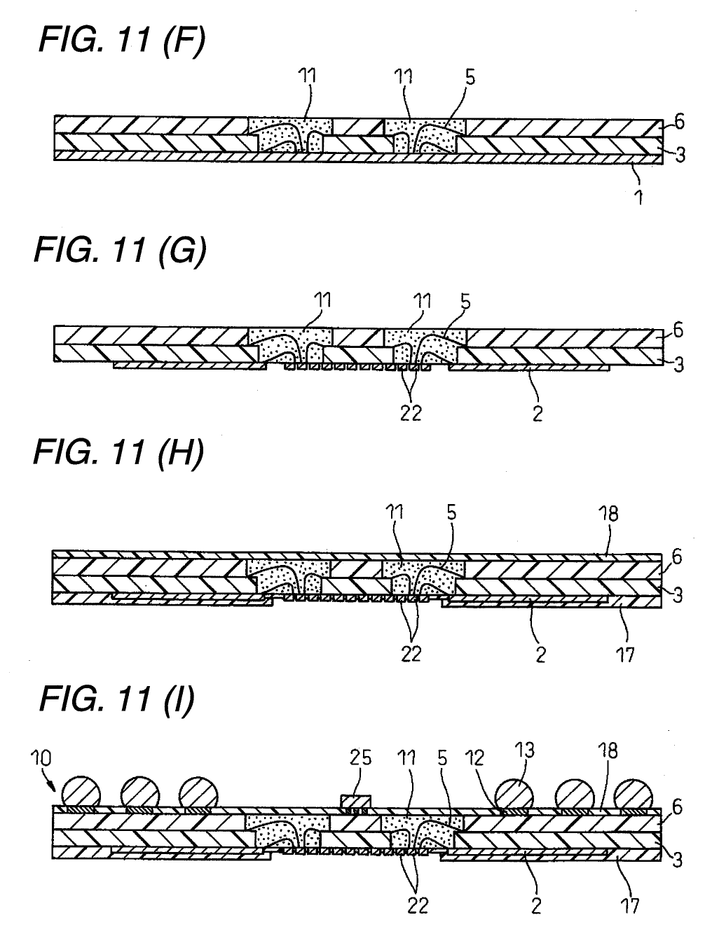

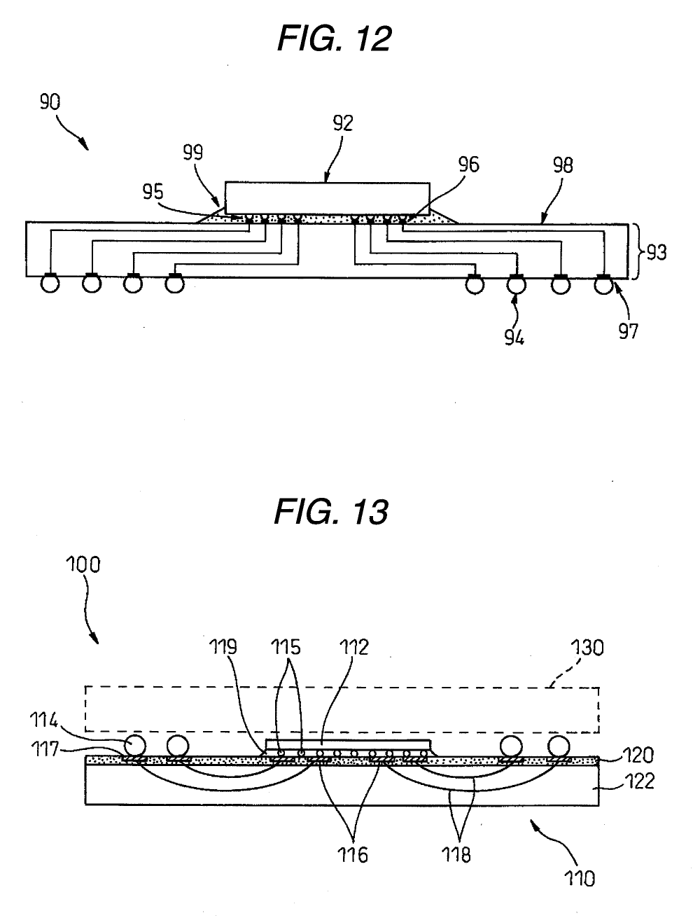

The multi-layered wiring substrate 10 according to the present invention is provided, in the interior thereof, with through holes 9 formed to expose the flip-chip receiving pads (refer to reference numeral 22 in FIG. 4) (Refer to, for example, FIGS. 9(B) and 11(D)). A resin material, preferably an organic resin material 11 is filled therein. The through hole 9 is formed in the form of a spacing having a predetermined shape in an area adjacent to the flip-chip receiving pad. The through hole 9 is normally composed of a rectangular parallelepiped spacing, and may be formed of a single rectangular spacing or a combination of two or more rectangular parallelepiped spacings. Where the through hole 9 is composed of a single rectangular parallelepiped spacing, it may be a box-shaped spacing as shown in FIG. 1, or although not illustrated, it may be, for example, a C-shaped deformation spacing. Where the through hole 9 is composed of a combination of two or more rectangular parallelepiped spacings, such an arrangement may be adopted, in which, for example, two slender rectangular parallelepipeds are juxtaposed, or another arrangement may be adopted. The through hole 9 may be easily formed, for example, by laser processing in the middle of forming a multi-layered wiring substrate or after forming the same. Further, the through hole 9 is provided to carry out wire bonding in the spacing thereof, and it does not usually include any electronic component such as a semiconductor element.

In the embodiment of the present invention, it is preferable that the through hole 9 is not necessarily formed so as to occupy a wide area in the multi-layered wiring substrate 10, but is formed so that only the signal portion of at least the flip-chip receiving pad of the multi-layered wiring substrate 10 is exposed, and wire bonding can be carried out at the portion. In the present invention, since the portion where wire bonding is carried out is made into a cavity, and at the same time, the flip-chip receiving pad is connected to the wiring layer of the substrate exposed to the inner wall of the through hole 9 or another connection terminal on the same surface or a different surface, it is possible to prevent the wires, which are used for wire bonding, from interfering with each other.

The multi-layered wiring substrate 10 according to the present invention is provided with a conductor wire 5 to electrically connect wirings, which are drawn out from the flip-chip receiving pads (refer to reference numeral 22 in FIG. 4), to the wiring layer 4 on the inner wall of the through hole 9 on the same surface and/or a different surface. The conductor wire 5 is three-dimensionally bent in the through hole 9 as shown in the drawings, and is connected to the wiring layer 4 of the multi-layered wiring substrate 10. The conductor wire 5 is composed of, for example, a wire material of conductor metal, or a wire material of conductor metal and an insulative coating layer to coat the outer circumference thereof, or a wire material of conductor metal, an insulative coating layer to coat the outer circumference thereof and a conductor layer. Also, as described later, where the through hole 9 is filled with an organic resin material, the structure of the conductor wire 5 changes based on whether or not the organic resin material has insulation properties. Furthermore, it is preferable that when the conductor wire 5 has a conductor layer, the conductor layer is connected to the grounding layer of the multi-layered wiring substrate. Also, in the drawing, although the conductor wire 5 is used for connection of the flip-chip receiving pad to the wiring layer, the flip-chip receiving pad may be connected to other parts of the multi-layered wiring substrate 10 via a conductor wire as necessary.

In the embodiment of the present invention, a conductor wire that is generally used as a bonding wire in the field of semiconductor devices may be advantageously used. However, it is preferable that the bonding wire used in the present invention is suitable for conditions that it is sealed in an insulative organic resin material filled in the through hole, and stably fixed, and the heat radiation characteristics thereof are improved. The conductor wire may be formed of an optional conductive material (conductor), preferably of a wire material of conductor metal. Suitable conductor metals may be, for example, gold, silver, copper, nickel, aluminum or an alloy thereof.

In addition, the conductor wire is such that the surface thereof is covered with a conductor layer, preferably, a conductor metal layer via an insulative coating layer, and it is preferable that the conductor wire has a coaxial structure the core of which is a conductor wire. That is, as shown in FIG. 5(D) which is a sectional view taken along the line D-D of FIG. 5(C), it is advantageous that the conductor wire has a coaxial structure composed of a conductor wire 5, an insulative coating layer 14 to coat the conductor wire one by one, and a conductor metal layer 15. The core of the conductor wire of the coaxial structure may be advantageously composed of a wire material of conductor metal, such as gold, silver, copper, nickel, aluminum or an alloy thereof as described above. In addition, the insulative coating layer to coat such a conductor wire may be preferably a coating layer of an insulative resin, for example, a coating layer of epoxy resin, polyimide resin, etc. Also, in the case of aluminum wire, an oxide film is effective. The resin coating layer may be formed by, for example, electrostatic coating, spray coating, dip coating, etc. Also, a conductor wire having the surface thereof coated with an insulative film, which is commercially available, may be used instead of coating the conductor wire with an insulative coating layer. The uppermost conductor metal layer may be formed of a conductor metal, such as gold, silver, copper, nickel, aluminum, or an alloy thereof. In particular, copper may be advantageously used as the conductor metal. The copper layer may be preferably formed by, for example, non-electrolytic copper plating or electrolytic copper plating. The conductor metal layer is preferably connected to the grounding layer (ground potential).

The conductor wire may have various sizes depending on the configuration and materials. For example, where the conductor wire has a coaxial structure, the diameter of the conductor wire core is normally approximately 20 μm to 40 μm. Also, the thickness of the insulative coating layer to coat the core is normally approximately 2 μm to 8 μm where, using a conductor wire having an insulative coating layer coated thereon at the surrounding thereof, wire bonding is carried out as it is. Further, where an insulative coating layer is coated on the surrounding of the conductor wire after wire bonding is carried out using a non-coated conductor wire, the thickness is normally 10 μm to 50 μm. The thickness of the insulative coating layer may vary according to a material used for the insulative coating layer and requirement for impedance matching. Also, in the multi-layered wiring substrate according to the present invention, an obtained multi-layered wiring substrate is caused to have capacitance by adjusting the material (relative dielectric constant) of the insulative coating layer and the thickness thereof in relation to a conductive organic resin material surrounding the conductor wire. As necessary, as regards the conductor metal layer formed by coating the insulative coating layer, the film thickness thereof may be varied in a wide range according to a desired effect as in the insulative coating layer. The film thickness of the conductor metal layer is normally in a range from approximately 5 to 30 μm.

Referring again to FIG. 5(D), in a conductor wire having a coaxial structure, it is preferable that the ratio of the inner diameter D0 of the metal layer 15 to the outer diameter D1 of the conductor wire 5 is approximately 1:3 to 6. By thus constructing the same, impedance may be further effectively matched in addition to preventing crosstalk from occurring.

In a multi-layered wiring substrate 10 according to the present invention, the through hole 9 is further filled with a resin material, preferably, an organic resin material 11. The organic resin material 11 may be variously changed according to the configuration of the multi-layered wiring substrate 10 and desired effects. For example, where the conductor wire 5 is composed of a conductor metal and an insulative coating layer to coat the outer circumference thereof, it is preferable that the through hole 9 is filled with an organic resin material of high thermal transmissivity. Further, it is preferable that the organic resin material is a metallic particle-dispersed type organic resin material. Where such an organic resin material is used, it is possible to improve the heat radiation characteristics of a multi-layered wiring substrate obtained, and to solve problems resulting from heat radiation in mounted electronic components, etc. According to another method, it is preferable that an organic resin material having a low resiliency index is used as the organic resin material. It is preferable that such an organic resin material normally shows a Young's modulus of approximately 1 to 100 Mpa. Where such an organic resin material is used, the stress resulting from a difference in the thermal expansion coefficient between the semiconductor device and the substrate can be relieved in a multi-layered wiring substrate obtained.

Further describing the organic resin material, the organic resin material filled in the through hole of a multi-layered wiring substrate is preferably an insulative organic resin material, and it may be filled in the through hole by, for example, a coating or potting method. For example, epoxy resin, polyimide resin, etc., may be listed as a suitable organic resin material. Also, a conductor wire is buried and sealed in the interior of the organic resin material filled in the through hole. However, in the embodiment of the present invention, such a wire sealing structure is not formed in a specific step separated from production of a multi-layered wiring substrate, however, preferably, it may be formed at an optional stage of production of the multi-layered wiring substrate.

The organic resin material may be used as it is. However, as touched on in the above, it may be favorably used in the form of a metallic particle-dispersed type organic resin material in which particles of a material having a high thermal transmissivity, preferably, metallic particles are dispersed. It is preferable that the metallic particle-dispersed type organic resin material is composed of a binder resin of the above-described organic resin material and a filler of metallic grains or powder having high thermal transmissivity, which are dispersed in the binder resin. A suitable filler may be, for example, gold, silver, copper, nickel or an alloy thereof. Further, the shape and size of the filler may be optionally varied, preferably spherical.

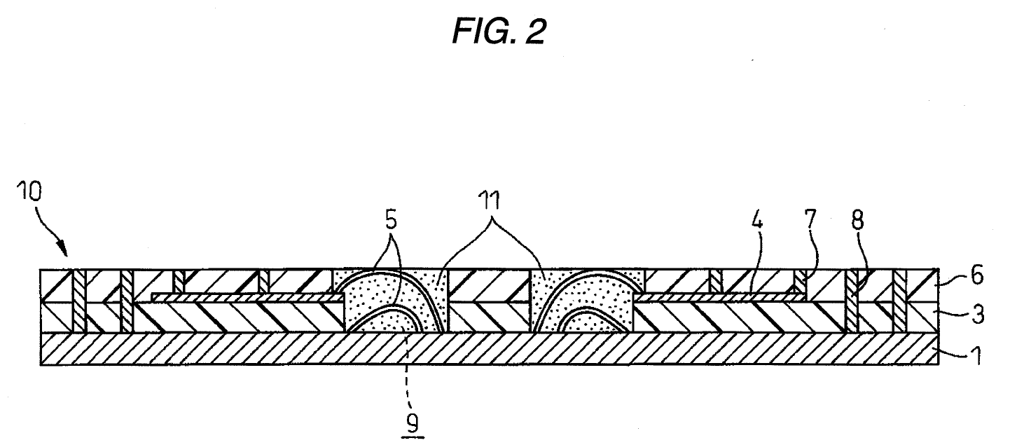

FIG. 2 is another preferred embodiment of a multi-layered wiring substrate according to the present invention. As understood by comparing the multi-layered wiring substrate 10 with the multi-layered wiring substrate 10 shown in FIG. 1, in the multi-layered wiring substrate 10 shown in FIG. 2, a part of the multi-layered wiring substrate 10 exists almost at the middle part of the through hole 9, and the through hole 9 is divided into two parts in two slender rectangular parallelepiped spacings of almost the same size, which are juxtaposed in the multi-layered wiring substrate 10. In the case of this example, such a configuration in which only the signal portion of the multi-layered wiring substrate 10 is exposed is particularly adopted. By adopting such a configuration, the portion of a metallic foil is prevented from being distorted particularly where the chip size is large and the size of the through hole becomes large, wherein such an effect can be brought about by which the step can be stabilized. In addition, since a part of the multi-layered wiring substrate 10 is disposed almost at the middle part of the through hole 9, the strength of the multi-layered wiring substrate 10 is intensified, wherein the handling efficiency can be improved.

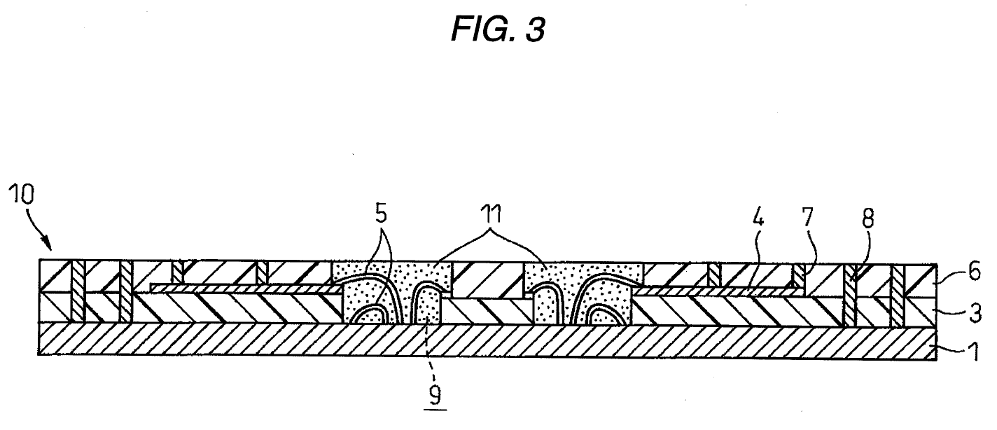

FIG. 3 shows another preferred embodiment of the multi-layered wiring substrate according to the present invention. As understood by comparing the multi-layered wiring substrate 10 with the multi-layered wiring substrate 10 shown in FIG. 1, in the multi-layered wiring substrate 10 shown in FIG. 3, a part of the multi-layered wiring substrate 10 also exists almost at the middle part of the through hole 9, the through hole 9 is divided into two parts in two slender rectangular parallelepiped spacings of almost the same size, which are juxtaposed in the multi-layered wiring substrate 10. In the case of this example, such a configuration in which only the signal portion of the multi-layered wiring substrate 10 is exposed is specifically adopted. In addition, the wire drawn out from the flip-chip receiving pad is connected to the wiring layer 4 on the inner wall of the multi-layered wiring substrate 10 in the through hole 9. The metallic foil 1 having the flip-chip receiving pad formed at a predetermined portion thereof is exposed in two through holes 9 opened in the insulative layer 2, and the organic resin material 11 is filled therein. Further, the portion where the flip-chip receiving pad is connected via the conductor wire is the wiring layer 4 having a part thereof exposed. By adopting such a configuration, such an effect by which external connection terminals can be formed at the middle part can be brought about in addition to the above-described effects. Also, since a part of the multi-layered wiring substrate 10 is disposed almost at the middle part of the through holes 9, the strength of the multi-layered wiring substrate 10 is intensified, wherein the handling efficiency thereof can be improved.

In a preferred embodiment, in a multi-layered wiring substrate according to the present invention, the metallic foil that is used as a precursor of a flip-chip receiving pad is further processed, wherein the multi-layered wiring substrate may already have a flip-chip receiving pad. The example showing this embodiment is a multi-layered wiring substrate 10, shown in FIG. 3, in which a flip-chip receiving pad is formed by processing the metallic foil 1 of the multi-layered wiring substrate 10 previously described with reference to FIGS. 1 and 2. In the present example, apart of the metallic foil is removed by the result of having selectively etched the metallic foil 1 according to a normal method, and at the same time, a part of the metallic foil is thinned to form a wiring layer (wiring pattern) 2. And, simultaneously therewith, flip-chip receiving pads (a group of external connection terminals) 22 can be formed.

In a preferred embodiment, the multi-layered wiring substrate according to the present invention further has a chip component, which is electrically connected to the lowermost wiring layer, in the interior of the through holes. Although the chip component may be a capacitor, a resistor, and an inductor, etc., it is not limited thereto. Also, other functional components may be mounted instead of these chip components. Further, by burying a chip component in the interior of the through hole, downsizing and compactification of obtained multi-layered wiring substrates can be achieved. In this case, it is preferable that an insulative organic resin material as described above is filled in the through hole by potting, etc., and the chip component is sealed with resin. In addition, in the method, a dam of an insulative material may be formed in advance around the connection part before the chip component and other components are connected. With such a structure, for example, in a case where the chip component is soldered, such an effect can be brought about, by which spread of the solder can be prevented from occurring.

Another aspect of the present invention resides in a semiconductor device. A semiconductor device according to the present invention is featured in that it includes a multi-layered wiring substrate according to the present invention, a semiconductor element mounted at a flip-chip receiving pad of the multi-layered wiring substrate, and an external component mounted at the opposite side of the flip-chip mounted side via an external connection terminal. The semiconductor element mounted at the flip-chip receiving pad is not especially limited. Therefore, it may include various types of semiconductor chips, for example, IC chip, LSI chip and others. Also, flip-chip packaging used for mounting of such a semiconductor chip may be carried out by forming a flip-chip receiving pad used as a mount according to a normal technique. A semiconductor element mounted in a multi-layered wiring substrate may be single or two or more. In addition, where a plurality of semiconductor elements are mounted, these semiconductor elements may be the same or different from each other. Further, a wiring layer and an external connection terminal (connection pad) may be formed on the flip-chip packaging surface of a multi-layered wiring substrate. Still further, for external connection terminals, bumps, for example, solder bumps and lands may be provided to connect a motherboard and other external components thereto at the side opposite to the flip-chip packaging side of the multi-layered wiring substrate. Furthermore, chip components may be further in a semiconductor device according to the present invention.

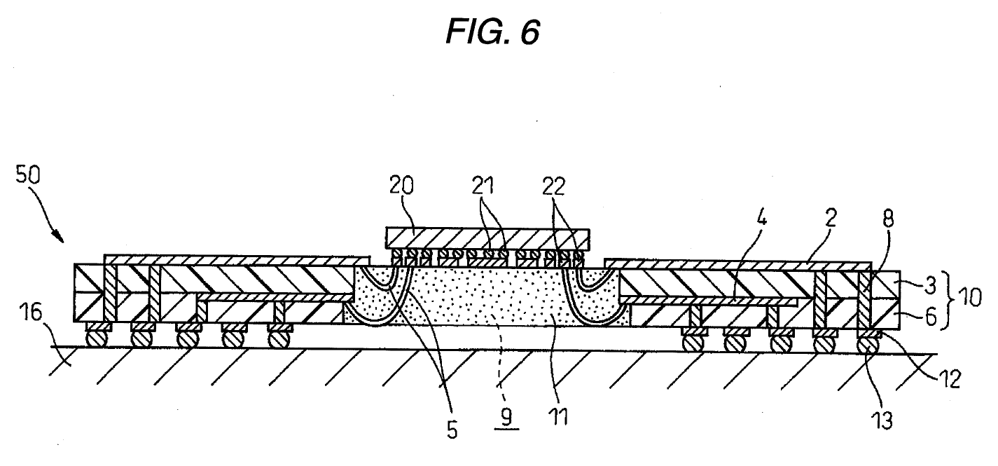

FIG. 6 is a sectional view showing a preferred embodiment of a semiconductor device according to the present invention. The illustrated semiconductor device 50 is an example in which a semiconductor chip 20 is mounted on the multi-layered wiring substrate 10 shown in FIG. 1 by flip-chip connection. The semiconductor chip 20 is mounted on a flip-chip receiving pad (connection pad) 22 on the multi-layered wiring substrate 10 via a bump 21 formed on the underside thereof. Also, a wiring layer 2 is provided on the same surface as the surface where the semiconductor element is mounted. Further, although not illustrated, another external connection terminal is provided, and an external device may be connected thereto. In this case, it is preferable that an arranged external device is provided with a mechanism for heat radiation. It is preferable that an organic resin material having high thermal transmissivity, for example, a metallic particle-dispersed type organic resin material having metallic particles (fillers) dispersed in an insulative organic resin material is filled in the through hole 9 of the multi-layered wiring substrate 10 to increase the heat radiation characteristics. Also, the portion of the bump 21 of the semiconductor chip 20 may be sealed by an underfill material In addition, the motherboard 16 is provided with bumps 13, and the multi-layered wiring substrate 10 is connected to the bumps 13 via the connection pads (conductor pads) 12. The respective bumps 13 are composed of, for example, solder bumps (SnAg). The motherboard 16 may be another external component.

In the semiconductor device 50, the conductor wire 5 that electrically connects the flip-chip receiving pad 22, wiring layers 2 and 4 to each other may have the configuration as described above. For example, it is preferable that, as previously described with reference to FIGS. 5(A) to 5(D), since the conductor wire 5 has a coaxial structure, it is preferable to attempt to reduce the conductor loss and to prevent and reduce crosstalk from occurring. Also, as regards the conductor wire 5, although not illustrated, the uppermost conductor metallic layer may be connected to the ground potential.

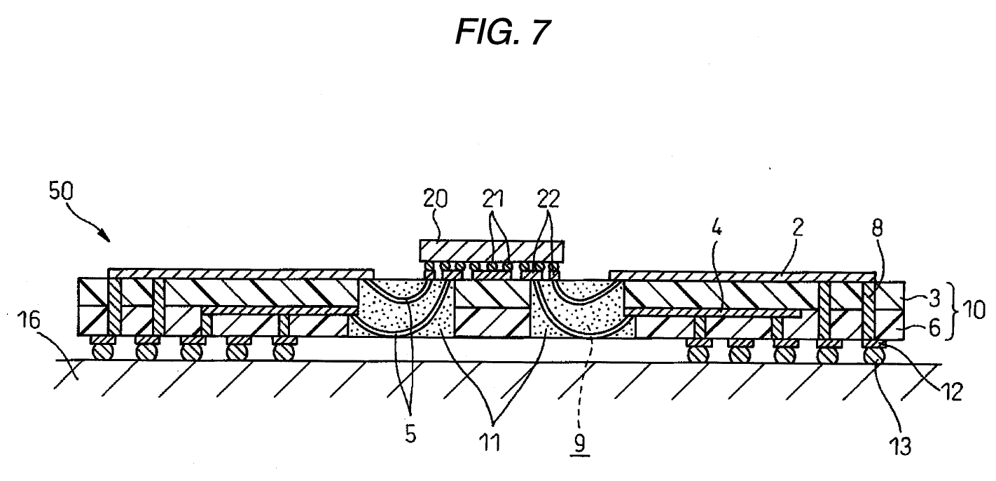

FIG. 7 is a sectional view showing another preferred embodiment of a semiconductor device according to the present invention. The semiconductor device 50 illustrated in the drawing is an example in which a semiconductor chip 20 is mounted on a multi-layered wiring substrate 10 shown in FIG. 2 by flip-chip connection. The semiconductor device 50 may have a configuration similar to that of the semiconductor device 50 previously described with reference to FIG. 6. However, it may be optionally subjected to modification or improvement. The semiconductor chip 20 is mounted on a flip-chip receiving pads 22 on the multi-layered wiring substrate 10 via bumps 21 formed on the underside thereof. Also, a wiring layer 2 is provided on the same surface as the surface where the semiconductor element is mounted. It is preferable that an organic resin material having high thermal transmissivity, for example, a metallic particle-dispersed type organic resin material having metallic particles (fillers) dispersed in an insulative organic resin material is filled in the through hole 9 of the multi-layered wiring substrate 10 to increase the heat radiation characteristics. In addition, the motherboard 16 is provided with bumps 13, and the multi-layered wiring substrate 10 is connected to the bumps 13 via the connection pads (conductor pads) 12. The respective bumps 13 are composed of, for example, solder bumps (SnAg).

In the semiconductor device 50, the conductor wire 5 that electrically connects the flip-chip receiving pad 22, wiring layers 2 and 4 to each other may have the configuration as described above. For example, it is preferable that, as previously described with reference to FIGS. 5(A) to 5(D), since the conductor wire 5 has a coaxial structure, it is possible to attempt to reduce the conductor loss and to prevent and reduce crosstalk from occurring. Also, as regards the conductor wire 5, although not illustrated, the uppermost conductor metallic layer may be connected to the ground potential.

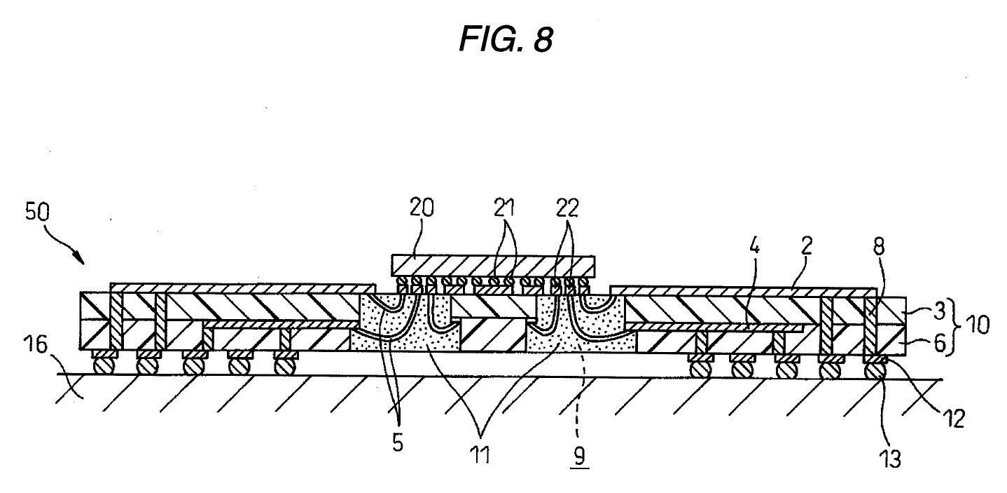

FIG. 8 is a sectional view showing another preferred embodiment of a semiconductor device according to the present invention. The semiconductor device 50 illustrated in the drawing is an example in which a semiconductor chip 20 is mounted on a multi-layered wiring substrate 10 shown in FIG. 3 by flip-chip connection. The semiconductor device 50 may have a configuration similar to that of the semiconductor device 50 previously described with reference to FIGS. 6 and 7. However, it may be optionally subjected to modification or improvement. The semiconductor chip 20 is mounted on flip-chip receiving pads 22 on the multi-layered wiring substrate 10 via bumps 21 formed on the underside thereof. Also, a wiring layer 2 is provided on the same surface as the surface where the semiconductor element is mounted. It is preferable that an organic resin material having high thermal transmissivity, for example, a metallic particle-dispersed type organic resin material having metallic particles (fillers) disposed in an insulative organic resin material is filled in the through hole 9 of the multi-layered wiring substrate 10 to increase the heat radiation characteristics. In addition, the motherboard 16 is provided with bumps 13, and the multi-layered wiring substrate 10 is connected to the bumps 13 via the connection pads (conductor pads) 12. The respective bumps 13 are composed of, for example, solder bumps (SnAg).

In the semiconductor device 50, the conductor wire 5 that electrically connects the flip-chip receiving pad 22, wiring layers 2 and 4 to each other may have the configuration as described above. For example, it is preferable that, as previously described with reference to FIGS. 5(A) to 5(D), since the conductor wire 5 has a coaxial structure, it is possible to attempt to reduce the conductor loss and to prevent and reduce crosstalk from occurring. Also, as regards the conductor wire 5, although not illustrated, the uppermost conductor metallic layer may be connected to the ground potential.

Another aspect of the present invention resides in a method for producing a multi-layered wiring substrate according to the present invention. A multi-layered wiring substrate of the present invention may be produced according to combinations of various techniques and various steps. The multi-layered wiring substrate of the present invention may be advantageously produced by the following steps:

(a) providing a multi-layered wiring substrate having two or more wiring layers and insulative layers being arranged one by one, which are formed in advance in a predetermined wiring pattern, and being equipped with through holes being spacings, having a predetermined shape, existing in areas adjacent to flip-chip receiving pads when forming the flip-chip receiving pads;
(b) providing a metallic foil as a precursor of the flip-chip receiving pads and wiring pads;
(c) connecting the metallic foil to the multi-layered wiring substrate in a state where the portions at which the flip-chip receiving pads of the metallic foil are planned to be formed is aligned with the multi-layered wiring substrate;
(d) bonding wires by which the portions at which the flip-chip receiving pads of the metallic foil are planned to be formed are three-dimensionally disposed at the planned portion of forming the other flip-chip receiving pads and/or the predetermined portion of wiring layers of the multi-layered wiring substrate by bending conductor wires;
(e) filling an organic resin material in the through holes and hardening the same; and
(f) forming the flip-chip receiving pads and wiring patterns by patterning the metallic foil. Also, according to the present invention, a step of mounting a semiconductor element may be added to the respective steps of such a method for producing a multi-layered wiring substrate, wherein it is possible to provide a method for producing a semiconductor device according to the present invention.

The method for producing a multi-layered wiring substrate as described above may be subjected to various improvements within the scope of the present invention. For example, the method according to the present invention may be advantageously carried out in the following modes.

(1) a mode further including, after the wire bonding step (d) and before the metallic foil patterning step, steps of forming an opening at a portion, corresponding to the vertical wiring portion to connect the wiring layers of the multi-layered wiring substrates to each other, of the metallic foil, of selectively etching the insulative layer of the multi-layered wiring substrate exposed at the opening by using the metallic foil as a mask, of forming a through hole so as to reach the wiring layer of the multi-layered wiring substrate, and of forming the vertical wiring portion to connect the metallic foil and the wiring layer of the multi-layered wiring substrate to each other filling the through hole with conductor metal.
(2) a mode of using, as the conductor wire in the wire bonding step (d), a conductor wire made of wire materials of conductor metal, a conductor wire made of wire materials of conductor metal and an insulative coated layer by which the outer circumferential surface thereof is coated, or a conductor wire made of wire materials of conductor metal and an insulative coated layer by which the outer circumferential surface thereof is coated one by one, and a conductor layer. The details of these conductor wires are as described above.
(3) a mode in which a chip component is connected to the metallic foil before or after the wire bonding step (d). In this mode, it is preferable that the chip component is connected after an insulative material layer portion is formed like a dam at the peripheral edge of the connected portion.

FIGS. 9(A) to 9(G) show a preferred method for producing a multi-layered wiring substrate according to the present invention in sequence, using the sectional views thereof. A multi-layered wiring substrate that is intended to be produced herein is a multi-layered wiring substrate as previously described with reference to FIG. 4. In addition, in the drawings, in order to simplify the description, since the wiring layers of the multi-layered wiring substrate are omitted, the detailed description of the wiring layers, etc., is to be referred to the description pertaining thereto in FIG. 4, etc.

First, as shown in FIG. 9(A), a metallic foil 1 that forms flip-chip receiving pads and a wiring layer (wiring pattern) in subsequent steps is prepared. That is, the metallic foil 1 may be called a precursor of the flip-chip receiving pads and the wiring layer. The metallic foil 1 may be formed of a copper foil and other conductor metals as described above. It is recommended that the metallic foil 1 is provided with alignment marks formed in advance in order to accurately and quickly carry out a positioning work in subsequent steps.

Next, as shown in FIG. 9(B), the metallic foil 1 is connected to a separately prepared multi-layered wiring substrate equipped with through holes 9 in a state where the planned portion of forming flip-chip receiving pads of the metallic foil 1 is aligned with the multi-layered wiring substrate. When connecting, an optional adhesive agent, for example, an adhesive sheet may be used. Also, according to another method, a build-up method may be adopted. In addition, although conveniently called a “multi-layered wiring substrate,” the multi-layered wiring substrate is strictly a multi-layered wiring substrate before being completed, that is, which is in the process of production. The multi-layered wiring substrate has two or more wiring layers and insulative layers 3 and 6 arranged one by one, which are formed in advance in a predetermined pattern, respectively, and is provided with through holes 9 being spacing having a predetermined shape, which can exist in areas adjacent to the flip-chip receiving pads.

After the connection step is completed, as shown in FIG. 9(C), wire bonding is carried out in the through holes 9. In the wire bonding step, the planned portions of the flip-chip receiving pads of the metallic foil 1 are three-dimensionally disposed by bending conductor wires 5 to the planned portions of the other flip-chip receiving pads and/or wiring layers (not illustrated) of the multi-layered wiring substrate.

Describing in further detail, in the wire bonding step, conductor wires 5 such as, gold wires are disposed at portions of the metallic foil 1, at which the flip-chip receiving pads are formed in subsequent steps, and the flip-chip receiving pads, wiring layers and other portions are electrically connected to each other. A general wire bonding technique may be used as the connecting means. The conductor wire 5 may have a diameter of, for example, 20 μm. Preferably, the conductor wire 5 may be used in the form of a conductor wire having a coaxial structure.

It is preferable that the conductor wire 5 is used in the form of a conductor wire having a coaxial structure. Where a conductor wire having a coaxial structure is used, preferably, the conductor wire 5 may be formed as shown in FIGS. 5(A) to 5(D). First, as shown in FIG. 5(A), one end of the conductor wire 5 is connected to the metallic foil 1. Next, as shown in FIG. 5(B), areas where the surface of connected conductor wire 5 and the area at which the conductor wire 5 and the formed portion of the flip-chip receiving pads are connected to each other are coated with an insulative material, thereby forming an insulative coated layer 14. After that, as shown in FIG. 5(C), the conductor metal layer 15 is formed by coating the insulative coated layer 14 with a conductor metal. The conductor metal layer 15 may be formed by, for example, a non-electrolytic plating method or a thermal decomposing method of metallic compounds. In addition, it is preferable that the conductor metal layer 15 is electrically connected to the ground potential. Thus, as shown in FIG. 5(D), that is, a sectional view taken along the line D-D in FIG. 5(C), a conductor wire having a coaxial structure, the core of which is the conductor wire 5, can be formed.

After the wire bonding is completed, it is a common procedure that an organic insulative resin material having fluidity is filled in the through holes 9 having conductor wires 5 wired in the spacing thereof. However, in the embodiment of the present invention, other steps may precede in response to a production process. For example, where a metallic column functioning as a conductor portion is used instead of forming the vertical wiring portion by plating, the metallic column may be erected on the metallic foil, following the wire bonding step.

Subsequently, as shown in FIG. 9(D), an organic insulative resin material 11 having fluidity is filled in the through holes 9 of a multi-layered wiring substrate and is hardened. It is preferable that the organic insulative resin material 11 is filled with a sufficient amount so that it can completely close up the through holes 9 and entirely covers the metallic foil 1 and the conductor wires 5. The organic insulative resin material is coated by, for example, potting a three-solution epoxy-based resin and is hardened while maintaining it at a temperature of, for example, 50 to 100° C.

Continuously, as shown in FIG. 9(E), flip-chip receiving pads 22 and a wiring layer 2 having a desired wiring pattern are formed by selectively patterning the metallic foil 1 in response to a desired wiring pattern. Etching of the metallic foil 1 may be carried out by a normal method using a suitable etchant according to the type of metallic foil. For example, where the metallic foil 1 is a copper foil, for example, ferric chloride may be used as the etchant.

After the flip-chip receiving pads 22, etc., are formed by etching, the solder resist layers 17 and 18 are formed on the outermost surface as shown in FIG. 9(F). Still after that, the conductor pads 12 are formed as shown in FIG. 9(G), and solder balls 13 are attached onto the conductor pads 12. A chip component 25 may be mounted on the solder resist layer 18. Through such a series of steps, it is possible to complete the multi-layered wiring substrate 10 that is a target.

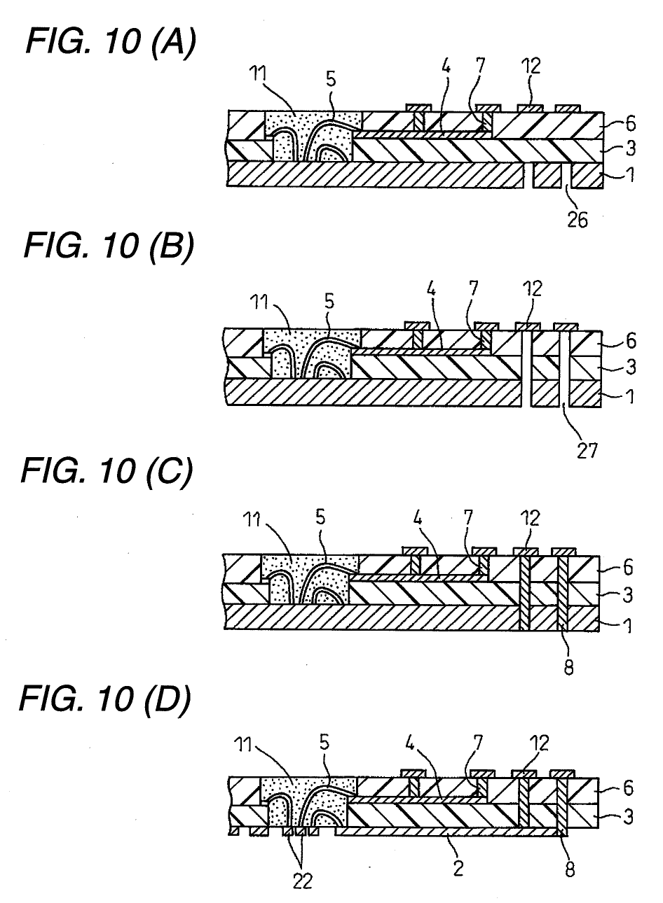

In this connection, in the embodiment of the present invention, it is also important to form a vertical wiring portion that penetrates the insulative layer. A description is sequentially given of a preferred mode in regard to formation of the vertical wiring portion with reference to FIGS. 10(A) to 10(D). Also, as has been understood from the drawing, FIGS. 10(A) to 10(D) show apart of the multi-layered wiring substrate 10 previously described with reference to FIG. 4.

First, as shown in FIG. 10(A), before patterning the metallic foil after the wire bonding step, an opening 26 is formed at a portion, of the metallic foil 1, corresponding to the vertical wiring portion (refer to reference numeral 8 in FIG. 10(C) and (D)) to which the wiring layer and/or connection pads of the multi-layered wiring substrate are connected. The opening 26 may be easily formed by, for example, selectively removing the portion, corresponding to the vertical wiring portion, of the metallic foil 1 after an etching resist layer is formed on the metallic foil.

Next, as shown in FIG. 10(B), through holes 27 that reach the wiring layer and/or connection pad of the multi-layered wiring substrate are formed by selectively etching the insulative layers 3 and 6 of the multi-layered wiring substrate exposed in the opening 26, using the etching resist layer and the metallic foil 1 therebelow as the mask. Also, in the illustrated example, etching is stopped at the connection pad 12, and the through holes 27 that reach the connection pads 12 from the metallic foil 1 are formed.

As shown in FIG. 10(C), a conductor metal is filled in the through holes 27 after the through holes are formed, and the vertical wiring portion 8 by which the metallic foil 1 and the connection pads 12 of the multi-layered wiring substrate are connected to each other. The vertical wiring portion 8 may be formed by plating of conductor metal, for example, by non-electrolytic copper plating and electrolytic copper plating on the entire surface of the metallic foil 1 one after another. By plating of such a conductor metal, the through holes 27 and the opening of the metallic foil 1 thereon can be filled with a conductor metal. After the plating is completed, the etching resist layer remaining on the uppermost layer is removed.

As shown in FIG. 10(D), the metallic foil 1 is selectively patterned according to a desired wiring pattern after the vertical wiring portion is formed. The patterning may be preferably carried out by etching. Through the etching, the flip-chip receiving pads 22 and the wiring layer 2 having a desired wiring pattern are obtained. In addition, the etching process corresponds to the step previously described with reference to FIG. 9(E).

FIGS. 11(A) to 11(I) show another preferred mode of a method for producing a multi-layered wiring substrate according to the present invention, using sectional views. A multi-layered wiring substrate intended to be produced herein is a multi-layered wiring substrate as previously described with reference to FIG. 4. Further, for simplification of the description, since the wiring layer of the multi-layered wiring substrate is omitted except a part thereof, as regards the detailed description of the wiring layer, FIG. 4 and the description pertaining thereto are referred to.

First, as shown in FIG. 11(A), a metallic foil 1 to form flip-chip receiving pads and a wiring layer (wiring pattern) is prepared in a subsequent step. The metallic foil 1 may be called a precursor of the flip-chip receiving pads and wiring layer as previously described. The metallic foil 1 may be formed of a copper foil and other conductor metals as described above.

Next, production of a multi-layered wiring substrate is commenced. Also, in this example, a description is based on production of a multi-layered wiring substrate of two-layered structure in order to simplify the description. However, the multi-layered wiring substrate is not limited thereto.

First, as shown in FIG. 11(B), an insulative layer 3 is formed on the metallic foil 1. The insulative layer 3 may be formed of an organic resin material of an insulative layer, such as epoxy resin, by a normal technique of, for example, coating or arranging an insulative sheet. The insulative layer 3 is equipped with an opening 9 (which finally becomes a through hole) in which an organic insulative resin material is filled in a subsequent step. The opening 9 may be formed in advance, otherwise it may be opened by normal means, such as etching, after the insulative layer 3 is formed if the insulative layer made of an insulative sheet and is such a type as has been arranged on the metallic foil 1.

Next, as shown in FIG. 11(C), a wiring layer 4 is formed at a predetermined portion on the insulative layer 3. The wiring layer 4 may be formed in a desired pattern by, for example, copper plating, etc.

After the wiring layer 4 is formed, as shown in FIG. 11(D), still another insulative layer 6 is formed on the insulative layer after the wiring layer 4 is formed. The insulative layer 6 may be embodied as in formation of the insulative layer 3. Thus, it is possible to obtain a multi-layered wiring substrate equipped with through holes 9 connected to the metallic foil 1. Also, at this stage, by repeating the step of forming the insulative layer 3 and the step of forming the wiring layer 4 following the former step, a multi-layered wiring substrate having a desired layer structure and openings (through holes) can be formed. In addition, although a multi-layered wiring substrate is referred to herein for convenience, the multi-layered wiring substrate is strictly a multi-layered wiring substrate which is before completion, that is, in the process of production.

After the multi-layered wiring substrate is completed, as shown in FIG. 11(E), wire bonding is carried out in the through holes 9 of the multi-layered wiring substrate. In the wire bonding step, the planned portions of forming flip-chip receiving pads of the metallic foil 1 are three-dimensionally disposed by bending conductor wires 5 at other planned portions of forming flip-chip receiving pads and/or predetermined portions of a wiring layer (not illustrated) of the multi-layered wiring substrate. In addition, since a detailed description has already been given of the conductor wire 5, the description thereof is omitted in this example.

After the wire bonding is completed, as shown in FIG. 11(F), an organic insulative resin material 11 having fluidity is filled in the through holes 9 of the multi-layered wiring substrate, and is hardened therein. It is preferable that the organic insulative resin material 11 completely closes up the through holes 9 and entirely covers the metallic foil 1 and the conductor wires 5. Also, since the organic insulative resin material 11 filled in the through holes 9 has already been described in detail, the description thereof is omitted herein.

Continuously, as shown in FIG. 11(G), the flip-chip receiving pads 22 and the wiring layer 2 having a desired wiring pattern are formed by selectively patterning the metal foil 1 according to a desired wiring pattern. Etching of the metallic foil 1 may be carried out by a normal technique using a suitable etchant according to the type of the metallic foil. For example, where the metallic foil 1 is, for example, a copper foil, for example, ferric chloride may be used as the etchant.

After the flip-chip receiving pads 22 are formed by etching, as shown in FIG. 11(H), solder resist layers 17 and 18 are formed on the outermost surface. Still after that, as shown in FIG. 11(I), conductor pads 12 are formed, and solder balls 13 are attached onto the conductor pads 12. Chip components 25 are mounted on the solder resist layers 18. Through such a series of steps, a multi-layered wiring substrate 10 that is a target can be completed.

### EMBODIMENT

Subsequently, a description is given of the present invention with reference to the embodiment thereof. The present invention is not limited by the following embodiment.

A copper foil (size: approximately 15 cm square) having alignment marks formed thereon and a multi-layered wiring substrate (refer to FIG. 1) equipped with a through hole at the middle part thereof are prepared. The copper foil is connected to the multi-layered wiring substrate and the through hole is covered with the copper foil. An epoxy-based adhesive agent is used for connection. Next, a plurality of predetermined two points are connected by a gold wire, whose diameter is 25 μm, on the surface formed by the copper foil and the multi-layered wiring substrate. Next, a silicone-based resin having a low resiliency ratio is supplied by potting so that it entirely covers the copper foil and the gold wires, wherein a resin layer (thickness: approximately 300 μm on the copper foil) with which the gold wires are sufficiently covered is formed. The resin layer is hardened by maintaining the temperature thereof at 50 to 100° C. Next, a through hole is formed at predetermined positions at the portion where the copper foil is connected to the multi-layered wiring substrate. In this example, the through hole whose diameter is approximately 80 μm is formed by using a CO₂ laser. Continuously, non-electrolytic copper plating and electrolytic copper plating are carried out on the metallic foil, wherein the through hole is filled with copper. After the plating is completed, a multi-layered wiring substrate having a copper foil is brought about.

Next, etching of the copper foil is carried out by an etchant made of ferric chloride, wherein flip-chip receiving pads and a wiring layer are formed. After the etching is completed, a solder resist is coated on the outermost surface by a thickness of approximately 20 μm to complete a multi-layered wiring substrate. In addition, plating such as nickel plating, gold plating, and solder plating may be carried out for the multi-layered wiring substrate as necessary. Also, in this example, although a gold wire is used as a conductor wire, a conductor wire such as a copper wire, an aluminum wire, and a coated wire having an organic insulative material coated on a conductor wire may be commercially available, and may be utilized.

What is claimed is:

1. A multi-layered wiring substrate comprising:
a wiring layer and an insulation layer alternately arranged, and
at one side thereof, pads connected to electronic components and wires for connecting the pads to the wiring layers, wherein
through holes filled with a resin material are provided in the multi-layered wiring substrate,
at least apart of the pad is formed on the resin material, and
at least a part of the wire is contained in the resin material.

2. The multi-layered wiring substrate according to claim 1, wherein
the through holes are provided so that at least the area at which the pad is provided is contained in the through holes.

3. The multi-layered wiring substrate according to claim 1, wherein
the wire is made of a wire material of conductor metal, of a wire material of conductor metal and an insulative coating layer to coat the outer circumference of the wire material of conductor metal, or of a wire material of conductor metal, an insulative coating layer to coat the outer circumference of the wire material of conductor metal one by one and a conductor layer.

4. The multi-layered wiring substrate according to claim 1, wherein
the wire is made of a wire material of conductor metal, an insulative coating layer to coat the outer circumference one by one and a conductor layer to be a co-axial structure, and
in the co-axial structure wire, a ratio of the inner diameter D0 of the conductor layer to the outer diameter D1 of the wire is within the range of 1:3 to 6.

5. The multi-layered wiring substrate according to claim 1, wherein
an organic resin material is filled in the through holes.

6. The multi-layered wiring substrate according to claim 5, wherein
the organic resin material is a metallic particle-dispersed type organic resin material.

7. The multi-layered wiring substrate according to claim 5, wherein
the organic resin material is an organic resin material having a low resiliency ratio.

8. The multi-layered wiring substrate according to claim 1, wherein
in the multi-layered wiring substrate, the wiring layers are electrically connected to each other by a vertical wiring portion.

9. A method for producing a multi-layered wiring substrate according to claim 1, comprising the steps of:
preparing a multi-layered wiring substrate in which a through hole is provided at a position corresponding to a portion, at which a pad to be electrically connected to an electronic component is formed, and a wiring layer and an insulative layer are alternately arranged;
preparing a metallic foil provided, at predetermined portions, with positions where a pad to be electrically connected to an electronic component is formed and a wiring pattern to be electrically connected to the multi-layered wiring substrate is formed, respectively;
connecting the multi-layered wiring substrate with the metallic foil;
electrically connecting the portion, at which the pad of the metallic foil is formed, with the wiring layer of the multi-layered wiring substrate by means of wires;
filling a resin material in the through holes; and
forming the pads and the wiring pattern at the predetermined portions by patterning the metallic foil.

10. A method for producing a multi-layered wiring substrate according to claim 1, comprising the steps of:
preparing a metallic foil provided, at predetermined positions, with portions where a pad to be electrically connected with an electronic component and a wiring pattern serving as a wiring layer of an outermost layer at a multi-layered wiring substrate to be obtained are respectively formed;
arranging an insulative layer provided with an opening at which the pad is formed, on the metallic foil;
forming a wiring layer on the insulative layer;
electrically connecting a portion of the metallic foil, at which the pad is formed, with the wiring layer by means of wires;
filling the opening with a resin material; and
forming the pad and the wiring pattern at the predetermined portions by patterning the metallic foil.

11. The method for producing a multi-layered wiring substrate according to claim 10, wherein
the step of arranging an insulative layer on the metallic foil and the step of forming a wiring layer on the insulative layer are repeated over a plurality of times.

12. The method for producing a multi-layered wiring substrate according to claim 9, wherein
after the step of connecting by means of wires and before the step of patterning the metallic foil,
an opening is formed at a portion, corresponding to the vertical wiring portion to connect the wiring layers of the multi-layered wiring substrates to each other, of the metallic foil,
the insulative layer of the multi-layered wiring substrate exposed at the opening is selectively etched using the metallic foil as a mask to form a through hole which reaches the wiring layer of the multi-layered wiring substrate, and
the vertical wiring portion to connect the metallic foil and the wiring layer of the multi-layered wiring substrate to each other is formed by filling the through hole with conductor metal.

13. A semiconductor device comprising:
a multi-layered wiring substrate according to claim 1,
a pad for connecting an electronic component provided at one side of the multi-layered wiring substrate,
an electronic component connected to the pad, and
an external connection terminal provided at the other side of the multi-layered wiring substrate.

14. The method for producing a multi-layered wiring substrate according to claim 10, wherein
after the step of connecting by means of wires and before the step of patterning the metallic foil,
an opening is formed at a portion, corresponding to the vertical wiring portion to connect the wiring layers of the multi-layered wiring substrates to each other, of the metallic foil,
the insulative layer of the multi-layered wiring substrate exposed at the opening is selectively etched using the metallic foil as a mask to form a through hole which reaches the wiring layer of the multi-layered wiring substrate, and
the vertical wiring portion to connect the metallic foil and the wiring layer of the multi-layered wiring substrate to each other is formed by filling the through hole with conductor metal.
